(19) United States
(12) Patent Application Publication
(10) Pub. No.: US 2025/0015172 A1
(43) Pub. Date: Jan. 9, 2025

(54) SEMICONDUCTOR DEVICE AND METHOD FOR OPERATING A SEMICONDUCTOR DEVICE

(71) Applicant: Hitachi Energy Ltd, Zürich (CH)

(72) Inventors: Tobias WIKSTROEM, Egliswil (CH); Quang Tien TRAN, Villach (AT); Hans-Günter ECKEL, Rostock (DE); Umamaheswara VEMULAPATI, Windisch (CH)

(21) Appl. No.: 18/711,822

(22) PCT Filed: Nov. 23, 2022
(86) PCT No.: PCT/EP2022/082918

§ 371 Date: May 20, 2024

(30) Foreign Application Priority Data
Dec. 3, 2021 (EP) 21212227.9

(51) Int. Cl. H01L 29/745; H01L 29/06; H01L 29/08; H01L 29/10; H01L 29/74

(52) U.S. Cl. CPC H01L 29/745; H01L 29/0696; H01L 29/083; H01L 29/1012; H01L 29/7416

(57) ABSTRACT

According to an embodiment, the semiconductor device (100) comprises a semiconductor body (1) with a first side (10) and a second side (20) opposite to the first side. The semiconductor device further comprises a first thyristor structure (I) and a second thyristor structure (II). The second thyristor structure is arranged laterally beside the first thyristor structure. Each of the first and the second thyristor structure comprises a first base region (11a, 11b) at the first side and agate electrode (1a, 1b) on the first side adjoining the assigned first base region. The first base regions of the two thyristor structures are regions of the semiconductor body and are of the same conductivity type. The gate electrodes of the thyristor structures are individually and independently electrically contactable.

The present disclosure relates to a semiconductor device and to a method for operating a semiconductor device. Moreover, the disclosure relates to a housing for such a semiconductor device and a semiconductor module comprising such a semiconductor device.

Document FR 2 560 440 A1 relates to a self-firing thyristor with integrated structure for on/off switching of high currents and its control circuit. Document US 2013/207157 A1 relates to a reverse-conducting power semiconductor device. Document U.S. Pat. No. 3,795,846 A relates to an integrated semiconductor device having functional regions isolated by pn-junctions therebetween. Haschimoto O et al: “2.5 KV-2000A MONOLITHIC REVERSE CONDUCTING GATE TURN-OFF THYRISTOR”, 1 Jan. 1986 (1986-01-01), ADVANCES IN COLLOID SCIENCE; [ADVANCES IN COLLOID SCIENCE], NEW YORK, INTERSCIENCE, US, PAGE(S) 388-392, XP000014619 relates to a 2.5 KV-2000A monolithic reverse conducting gate turn-off thyristor.

There is a need for an improved semiconductor device, e.g. for a semiconductor device with a controlled turn-on behavior. Furthermore, there is a need for a method for operating such a semiconductor device.

Embodiments of the disclosure relate to an improved semiconductor device, e.g. to a semiconductor device with a controlled turn-on behavior, a method for operating such a semiconductor device, a housing for such a semiconductor device and a semiconductor module with such a semiconductor device.

First, the semiconductor device is specified.

According to an embodiment, the semiconductor device comprises a semiconductor body with a first side and a second side opposite to the first side. The semiconductor device further comprises a first thyristor structure and a second thyristor structure. The second thyristor structure is arranged laterally beside the first thyristor structure. Each of the first and the second thyristor structure comprises a first base region at the first side and a gate electrode on the first side adjoining and being in electrical contact with the assigned first base region. The first base regions of the two thyristor structures are of the same conductivity type and are each a region of the semiconductor body. The gate electrodes of the thyristor structures are individually and independently electrically contactable.

Thyristor-type semiconductor devices, designed to establish a self-sustaining, gate-current-independent, on-state, show a non-controllable turn on behavior called triggering or latching. When latched, the anode-cathode voltage collapses rapidly and unrecoverably. The associated rapid rise in the anode current can be problematic for a diode connected in a power electronic circuit that forces it to perform reverse recovery under a large negative rate of current change. In order not to overstress the diode or any other circuit element with limited capability for rapid current rate of change, an inductive snubber is often used to limit current transients. Most often, the added circuit impedance (“choke”) causes inductive voltages during switching that necessitate a voltage-limiting snubber circuit (“clamp”) consisting of a diode, resistor and a capacitor. The snubber circuit elements carry significant size, cost and complexity that threaten to limit the applicability of the whole arrangement needed for reliable operation of thyristor-based circuits.

The present disclosure is based, inter alia, on the idea to provide a fully controllable semiconductor device with two thyristor structures. This allows the snubbers to be omitted. The first thyristor structure and the second thyristor structure can be independently supplied with a gate current. In this way, the first thyristor structure can be turned on before the second thyristor structure is turned on. For example, the first thyristor structure is designed such that it does not latch when turned on by the assigned gate electrode. Therefore, the anode current and/or voltage transients of the first thyristor structure can be controlled by the gate current. The appearance of the anode-cathode voltage drop can then be smoothly handed over to the second thyristor structure, which can be turned on by the respective gate electrode afterwards.

Here and in the following, an element or a region is “assigned” to another element or region if they belong to the same thyristor structure or the same thyristor cell, respectively. The expression “respective” is used in the same sense.

The semiconductor device specified herein may be a power semiconductor device. For example, the semiconductor device is a gate turn-off thyristor (GTO) or a gate-commutated thyristor (GCT) or an integrated gate-commutated thyristor (IGCT) or a reverse-conducting IGCT (RC-IGCT) or an asymmetric IGCT (AS-IGCT) or a reverse blocking IGCT (RB-IGCT).

The semiconductor body may be a contiguous body, e.g. a semiconductor body formed in one piece. For example, the semiconductor body extends contiguously over the first and the second thyristor structure. The first and the second thyristor structure may each comprise or be assigned a portion of the semiconductor body. In other words, the semiconductor device may be or may comprise a semiconductor chip with one semiconductor body and the first and the second thyristor structure may be integrated into this semiconductor chip.

The first and the second side of the semiconductor body may run essentially parallel to each other and/or parallel to a main extension plane of the semiconductor body.

The first thyristor structure and the second thyristor structure are arranged laterally beside each other. Here and in the following, a lateral direction is, e.g., a direction parallel to the first side and/or parallel to the second side and/or parallel to the main extension plane of the semiconductor body. For example, the first thyristor structure is arranged in a center of the semiconductor body and/or the second thyristor structure laterally surrounds the first thyristor structure.

The first thyristor structure comprises a gate electrode and a first base region. Likewise, the second thyristor structure comprises a gate electrode and a first base region. Here and in the following when a structure, like a thyristor structure, comprises an element, like an electrode, or a region, this means, e.g., that the element or region is assigned to this structure on a one-to-one basis.

The first base regions of the thyristor structures are of the same conductivity type, which might be hole-conduction (also referred to as p-conducting or p-doped). Alternatively, it may be electron conduction (also referred to as n-conducting or n-doped). Thus, the first base regions of the two thyristor structures may both either be p-doped or n-doped.

The first base regions may adjoin the first side or may form part of the first side, respectively. The gate electrodes of the two thyristor structures adjoin the assigned first base regions, i.e. are in direct mechanical contact with the assigned first base region.

The different regions of the semiconductor body defined here and in the following may each have a homogeneous doping concentration over their entire volume. The regions may be formed contiguously, e.g. without interruptions. “Homogeneous” means homogeneous within the limits of the manufacturing tolerance.

The gate electrodes of the two thyristor structures are individually and independently electrically contactable. For instance, they are only electrically connected through a reverse-biased pn-junction of the semiconductor body and therefore are practically insulated. The two gate electrodes may be set to different electrical potentials during operation of the semiconductor device. For example, gate currents may be independently and individually impressed through the two gate electrodes of the two thyristor structures.

According to a further embodiment, the first thyristor structure is designed such that it does not latch when turned on by a (reasonable) gate current impressed through the assigned gate electrode. Thus an anode-cathode current through the first thyristor structure can be controlled by the gate current, e.g. the magnitude of the anode-cathode current can be controlled by the magnitude of the impressed gate current through the assigned gate electrode. For example, the first thyristor structure is designed such that it is not self-sustaining, e.g. it turns-off automatically when the gate current through the assigned gate electrode is turned off. The second thyristor structure may be designed such that it latches when turned on. For example, the second thyristor structure is self-sustaining.

Whether or not the first and the second thyristor structure latch can be set, for example, by correspondingly adjusting the doping concentrations in the thyristor structures. That is, by appropriately choosing the doping concentration in one or more regions of the semiconductor body assigned to a thyristor structure, it can be set whether the thyristor structure latches or not.

Indeed, the non-latching behavior can be achieved in several ways, e.g. by adjusting the doping concentration(s) in the semiconductor body. For example, the doping concentration in the first base region and/or in a second base region of the first thyristor structure can be increased until the desired non-latching behavior is achieved. Additionally or alternatively, the doping concentration in a first and/or second emitter region of the first thyristor structure can be reduced until the desired non-latching behavior is achieved.

The second base region as well as the first and second emitter regions will be introduced further below.

According to a further embodiment, at least one region of the semiconductor body assigned to the first thyristor structure has a different doping concentration than a corresponding region of the semiconductor body assigned to the second thyristor structure. The corresponding region of the second thyristor structure is a region which has the same function in the thyristor structure. For example, the doping concentrations in the two corresponding regions differ from each other by a factor of least 2 or at least 5 or at least 10 or at least 100 or at least 1000.

According to a further embodiment, the first base region of the first thyristor structure has a greater doping concentration than the first base region of the second thyristor structure. Due to this higher doping concentration, the current gain can be reduced.

The second thyristor structure may be designed like a standard thyristor structure, e.g. like a GTO thyristor structure. With the higher doped first base region, the first thyristor structure does, e.g., not latch when it is turned on by the reasonably controlled gate electrode.

According to a further embodiment, the semiconductor device comprises a diode structure, e.g. an anti-parallel diode structure or a free-wheeling diode structure. The diode structure is, e.g., incorporated into the semiconductor body. This means that the diode structure comprises a portion of the semiconductor body or is assigned a portion of the semiconductor body, respectively.

The diode structure may be arranged laterally between the first and the second thyristor structure. Alternatively, the diode structure may be laterally surrounded by the first and the second thyristor structure or the diode structure may laterally surround the first and the second thyristor structure.

The diode structure may comprise a first diode electrode, e.g. on the first side of the semiconductor body. For example, the first diode electrode is individually and independently electrically contactable from the gate electrodes of the thyristor structures. Furthermore, the diode structure may comprise a second diode electrode on the second side of the semiconductor body. The diode structure may also comprise a first diode region and a second diode region, wherein the two diode regions are both regions of the semiconductor body. The first diode region and the second diode region are of different conductivity types. For example, the first diode region is of a second conductivity type and the second diode region is of a first conductivity type or vice versa. For example, here and in the following, the first conductivity type is electron conduction and the second conductivity type is hole conduction.

The first diode region may adjoin the first diode electrode and/or the second diode region may adjoin the second diode electrode. The first and the second diode region may adjoin each other. A pn-junction may be formed between the first and the second diode region. With the integrated diode structure, the semiconductor device is a reverse conducting (RC) semiconductor device.

The first diode region is, e.g., separated from either of the thyristors' first base regions by means of a reverse-biased pn-junction of the semiconductor body.

Each of the electrodes specified herein may be metallic. Moreover, besides the first and the second thyristor structure, the semiconductor device may comprise further thyristor structures. For example, the further thyristor structures also comprise a portion of the semiconductor body or may be assigned a portion of the semiconductor body, respectively. Likewise, the semiconductor device may comprise one or more further diode structures, which may each be designed like the diode structure described herein.

According to a further embodiment, the area of the first thyristor structure is smaller than the area of the second thyristor structure. For example, the area of the first thyristor structure is at most 50% or at most 30% or at most 20% or at most 10% of the area of the second thyristor structure. This may be advantageous in terms of the thermal management of the semiconductor device.

The area of a structure is herein defined, e.g., as the area of a certain region of the structure when projected onto the main extension plane of the semiconductor body or on the first side or on the second side. For example, the area of a thyristor structures is defined as the area of the projected, assigned first base region or of the projected gate electrode or of the projected active region. Likewise, the area of a diode structure may be defined as the area of the projected, assigned first diode region or the projected first diode electrode or the projected active region.

According to a further embodiment, the area of the second thyristor structure is at least 60% or at least 80% or at least 90% of the total area of the semiconductor device. The total area of the semiconductor device may be the total area of the first side and/or of the second side.

According to a further embodiment, the doping concentration in the first base region of the first thyristor structure is at least 2-times or at least 5-times or at least 10-times or at least 100-times or at least 1000-times the doping concentration of the first base region of the second thyristor structure.

According to a further embodiment, the second thyristor structure is a gate-commutated thyristor structure with a plurality of thyristor cells. For example, the different thyristor cells are connected or connectable in parallel. Each thyristor cell may comprise a portion of the first base region of the second thyristor structure and a portion of the gate electrode of the second thyristor structure.

According to a further embodiment, the first base regions of the first and the second thyristor structures are separated from each other by at least one separation region of the semiconductor body being of a different, i.e. opposite, conductivity type than the first base regions. For instance, the first base regions of the two thyristor structures are everywhere separated from each other by the at least one separation region so that there is no direct contact between the two first base regions. For example, the first base regions are p-conducting and the at least one separation region in between is n-conducting.

According to a further embodiment, the first base region of the first thyristor structure is formed contiguously, e.g. without interruptions.

According to a further embodiment, the first base region of the second thyristor structure is formed contiguously, i.e. without interruptions.

According to a further embodiment, the first thyristor structure comprises a first main electrode on the first side, a second main electrode on the second side, a first emitter region at the first side adjoining and being in electrical contact with the first main electrode of the first thyristor structure, a second emitter region at the second side adjoining and being in electrical contact with the second main electrode of the first thyristor structure and a second base region. The first main electrode may be a cathode, the second main electrode may be an anode or vice versa.

According to a further embodiment, the second thyristor structure comprises a first main electrode on the first side, a second main electrode on the second side, a first emitter region at the first side adjoining and being in electrical contact with the first main electrode of the second thyristor structure, a second emitter region at the second side adjoining and being in electrical contact with the second main electrode of the second thyristor structure and a second base region. Also here, the first main electrode may be a cathode, the second main electrode may be an anode or vice versa.

In the case of several thyristor cells, each thyristor cell may comprise its own first main electrode on the first side and/or its own first emitter region at the first side adjoining the assigned first main electrode.

According to a further embodiment, the first emitter regions of the thyristor structures, the second emitter regions of the thyristor structures and the second base regions of the thyristor structures are each a region of the semiconductor body.

According to a further embodiment, the first emitter regions and the second base regions of the thyristor structures are each of the first conductivity type, e.g. n-conducting.

According to a further embodiment, the first base regions and the second emitter regions of the thyristor structures are each of the second conductivity type, e.g. p-conducting.

According to a further embodiment, in vertical direction, the second base regions of the thyristor structures are each arranged between the assigned second emitter region and the assigned first base region. The vertical direction is a direction perpendicular to the lateral directions, i.e. perpendicular to the first and/or the second side and/or the main extension plane of the semiconductor body. Thus, the expression “vertical” does not necessarily characterize a direction parallel to the direction of gravity. Rather, it is used to specify directions running perpendicular to the lateral directions.

According to a further embodiment, in vertical direction, the first base regions of the thyristor structures are each arranged between the assigned first emitter region and the assigned second base region.

In other words, when viewed in direction from the first side to the second side, each thyristor structure comprises a first emitter region, a first base region, a second base region, and a second emitter region in this order.

Pn-junctions may be formed between the first emitter regions and the first base regions and/or between the first base regions and the second base regions and/or between the second base regions and the second emitter regions. Neighboring regions may adjoin each other.

According to a further embodiment, the first emitter region of the first thyristor structure has a lower doping concentration than the first emitter region of the second thyristor structure. For example, the doping concentration in the first emitter region of the second thyristor structure is at least 2-times or at least 5-times or at least 10-times or at least 100-times or at least 1000-times the doping concentration in the first emitter region of the first thyristor structure.

According to a further embodiment, the second emitter region of the first thyristor structure has a lower doping concentration than the second emitter region of the second thyristor structure. For example, the doping concentration in the second emitter region of the second thyristor structure is at least 2-times or at least 5-times or at least 10-times or at least 100-times or at least 1000-times the doping concentration in the second emitter region of the first thyristor structure.

According to a further embodiment, the second base region of the first thyristor structure has greater doping concentration than the second base region of the second thyristor structure. For example, the doping concentration in the second base region of the first thyristor structure is at least 2-times or at least 5-times or at least 10-times or at least 100-times or at least 1000-times the doping concentration of the second base region of the second thyristor structure.

Also with different doping concentrations in the first emitter regions and/or second emitter regions and/or second base regions, as specified in the last paragraphs, the first thyristor structure will not latch when it is turned on by the reasonable controlled gate electrode so that the anode-cathode voltage drop can be smoothly handed over to the second thyristor structure.

According to a further embodiment, the first and/or the second emitter region of the first and/or second thyristor structure are passed through by one or more shorts. A short is a region of the semiconductor body passing through an emitter region and being of the opposite conductivity type than the emitter region through which it passes. The short(s) may adjoin and may be in electrical contact with the first or the second main electrode, respectively. The short(s) through a first emitter region may be electrically connected to the assigned first base region and/or may have the same doping concentration as the assigned first base region. The short(s) through a second emitter region may be connected to the assigned second base region and/or may have the same doping concentration as the assigned second base region. In other words, the short(s) through a first emitter region may electrically connect the assigned first main electrode with the assigned first base region. The short(s) through a second emitter region may electrically connect the assigned second main electrode with the assigned second base region.

For example, with a short in the first and/or second emitter region of the first thyristor structure, the first thyristor structure will not latch when it is turned on by the reasonable controlled gate electrode so that the anode-cathode voltage drop can be smoothly handed over to the second thyristor structure.

According to a further embodiment, the second base regions of the thyristor structures are formed by a contiguous second base layer extending over the first and the second thyristor structure. For example, the second base layer is continuous of the first conductivity type. In other words, the second base regions are connected to each other. For example, the second base regions have the same doping concentration within the limits of the manufacturing tolerances. In this case, the second base layer may be doped homogeneously.

According to a further embodiment, the second emitter regions of the thyristor structures are formed by a contiguous second emitter layer extending over the first and the second thyristor structure. For example, the second emitter layer is continuous of the second conductivity type. In other words, the second emitter regions are connected to each other. For example, the second emitter regions have the same doping concentration within the limits of the manufacturing tolerances. In this case, the second emitter layer may be doped homogeneously.

According to a further embodiment, the second main electrodes of the first and the second thyristor structures are formed by a contiguous second main electrode extending over the first and the second thyristor structure.

According to a further embodiment, the first emitter regions of the thyristor structures have the same doping concentration within the limits of the manufacturing tolerances.

According to a further embodiment, the second base regions each comprise a lower doped drift region and a higher doped buffer region. That means that the buffer region has a higher doping concentration than the drift region in each second base region. Accordingly, the second base layer may comprise a lower doped drift layer and a higher doped buffer layer. For example, the doping concentration of the buffer regions or the buffer layer is at least 10-times or at least 100-times or at least 1000-times or at least 10000-times the doping concentration of the drift regions or of the drift layer. The buffer regions/layer may be arranged vertically between the drift regions/layer and the second emitter regions/layer.

In case the second base regions of the first and the second thyristor structure have different doping concentrations, the buffer regions of the two thyristor structures may have different doping concentrations whereas the drift regions may have the same doping concentration within the limits of manufacturing tolerance.

According to a further embodiment, the first thyristor structure and the second thyristor structure are arranged in an alternating manner in a lateral direction. Thus, a line parallel to the first side and/or second side and/or the main extension plane of the semiconductor body, alternately crosses sections of the first thyristor structure and of the second thyristor structure. For example, the first thyristor structure engages with the second thyristor structure in a comb-like manner. Such an arrangement may be advantageous in terms of thermal management.

For example, the first and the second thyristor structure both have a rotational symmetry with respect to a rotation axis. The rotation axis may run parallel to the vertical direction. A circle line around the rotation axis may alternately cross sections of the first thyristor structure and of the second thyristor structure.

Next, the housing for the semiconductor device is specified. The housing is, e.g., configured for a semiconductor device according to any embodiment described herein.

According to an embodiment of the housing, the housing comprises at least two main electrode structures for electrically contacting the first and the second main electrodes of the thyristor structures and/or of the diode structure. Moreover, the housing comprises two or more auxiliary electrode structures, a first auxiliary electrode structure for electrically contacting the gate electrode of the first thyristor structure and a separate second auxiliary electrode structure for electrically contacting the gate electrode of the second thyristor structure. The electrode structures may be embedded in a base body of the housing. For example, the base body is of or comprises plastic or ceramic.

Next, the semiconductor module is specified. The semiconductor module may comprise the semiconductor device disclosed herein arranged in the housing disclosed herein. The electrode structures of the housing are then, e.g., electrically connected to the appropriate electrodes of the semiconductor device. The semiconductor module is, e.g., a power semiconductor module.

Next, the method for operating a semiconductor device is specified. The method is, e.g., suitable for operating the semiconductor device according to any embodiment described herein. Consequently, all features disclosed in connection with the semiconductor device are also disclosed for the method and vice versa.

According to an embodiment of the method, the method comprises a first step, in which a first gate current is impressed through the gate electrode of the first thyristor structure while no current is impressed through the gate electrode of the second thyristor structure. Then, in a second step, a second gate current is impressed through the gate electrode of the second thyristor structure. When executing the second step, the first gate current may still be impressed through the gate electrode of the first thyristor structure.

The first gate current may be impressed between the gate electrode and the first main electrode of the first thyristor structure. The second gate current may be impressed between the gate electrode and the first main electrode of the second thyristor structure. During these steps, an anode-cathode voltage may be applied between the first main electrodes and the second main electrode(s) of the thyristor structures. By impressing the first gate current, the first thyristor structure is switched into the on-state. By impressing the second gate current, the second thyristor structure is switched into the on-state.

By first impressing a first gate current through the gate electrode of the first thyristor structure, control over the anode voltage is retained through controlling the gate current magnitude which moderates the rate of current commutation from a diode in forward conduction, for example a freewheeling diode, that is forced by the power electronic circuit to perform reverse recovery following the turn-on event. Hence, the diode in the example enjoys protection from unsafe reverse-recovery conditions thanks to moderation of its rate of current decay.

According to a further embodiment, the second gate current is impressed after collapse or decay or drop of the anode-cathode voltage in the semiconductor device. Due to the first thyristor structure, the collapse or decay or drop, respectively, in the anode-cathode voltage is controlled. The second step is only performed once the anode-cathode voltage has decayed, e.g. to safe values. The anode-cathode voltage may be around 10% of the DC-link voltage.

In the on-states of the first and second thyristor structures, the first and/or the second gate current can be turned off. As long as current between the anode and the cathode is above the holding-current, at least the second thyristor structure, eventually also the first thyristor structure, remains in the on-state.

Reducing the second gate current to zero is possible but often not done in practice. A relatively small DC “back porch” current is normally retained throughout the conduction period. This practice has a range of motivations that are related to keeping the second thyristor latched under all circumstances.

Reducing the first gate current to zero may turn off the first thyristor structure in normal operation. Normal operation is assuming that the second thyristor structure is on. As conceived, the first thyristor structure won't retain significant capability for hard turn-off and will fail almost any attempt to do so.

According to a further embodiment, the method comprises a third step in which a turn-off gate current is impressed through the gate electrode of the second thyristor structure and/or through the gate electrode of the first thyristor structure. The turn-off gate currents may be impressed simultaneously through the first and second thyristor structure. In this step, the thyristor structures are switched into the respective off-state.

Hereinafter, the semiconductor device and the method for operating a semiconductor device will be explained in more detail with reference to the drawings on the basis of exemplary embodiments. The accompanying figures are included to provide a further understanding. In the figures, elements of the same structure and/or functionality may be referenced by the same reference signs. It is to be understood that the embodiments shown in the figures are illustrative representations and are not necessarily drawn to scale. In so far as elements or components correspond to one another in terms of their function in different figures, the description thereof is not repeated for each of the following figures.

For the sake of clarity, elements might not appear with corresponding reference symbols in all figures.

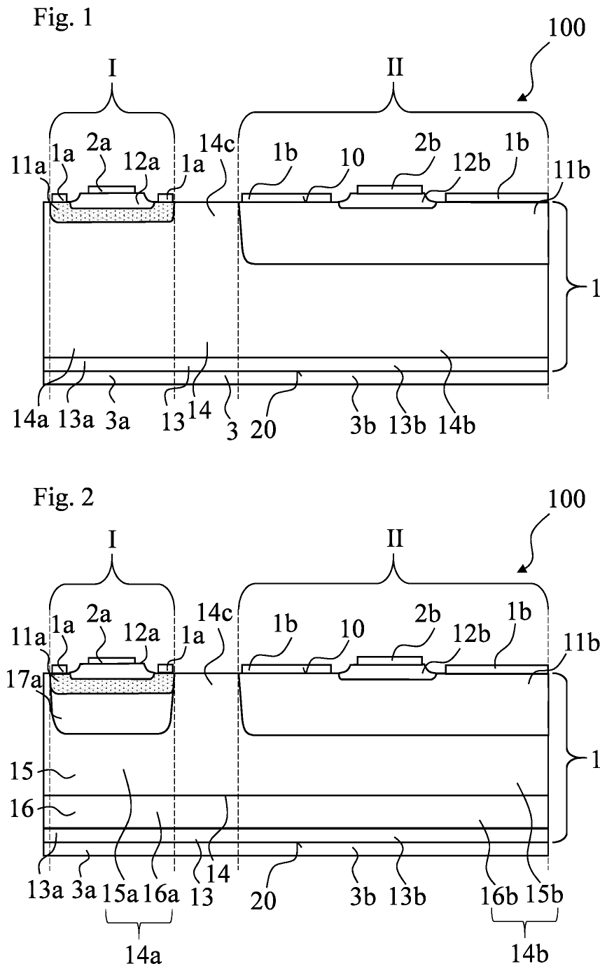

FIGS. 1 and 2 show different exemplary embodiments of a semiconductor device in a cross-sectional view,

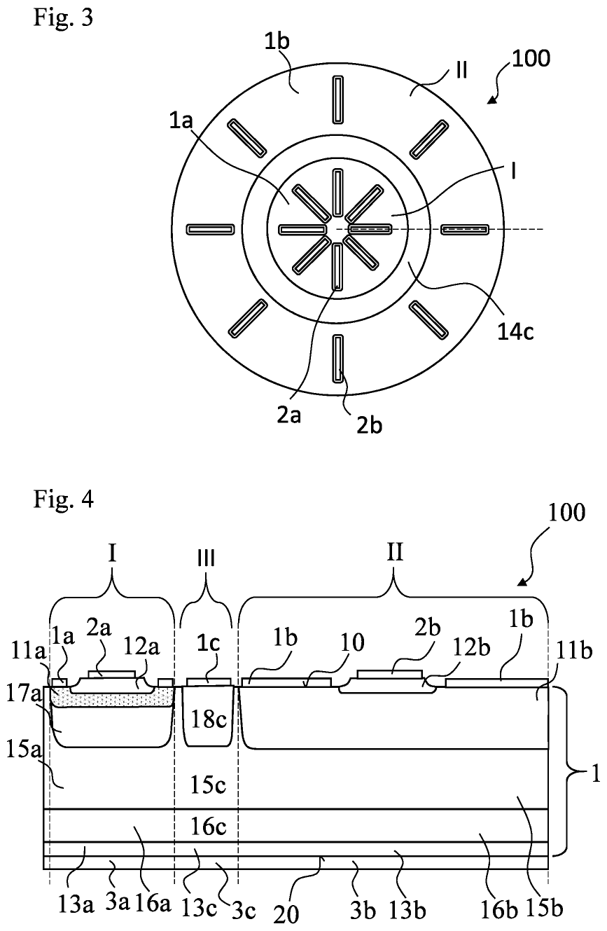

FIG. 3 shows the exemplary embodiment of FIG. 1 or 2 in a top view,

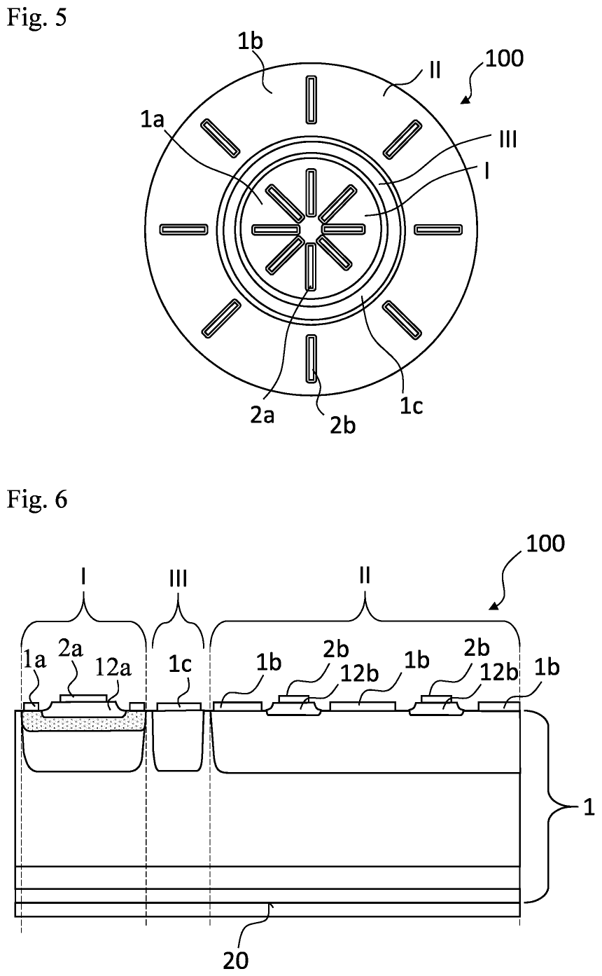

FIGS. 4 and 5 show a further exemplary embodiment of a semiconductor device in a cross-sectional view and a top view,

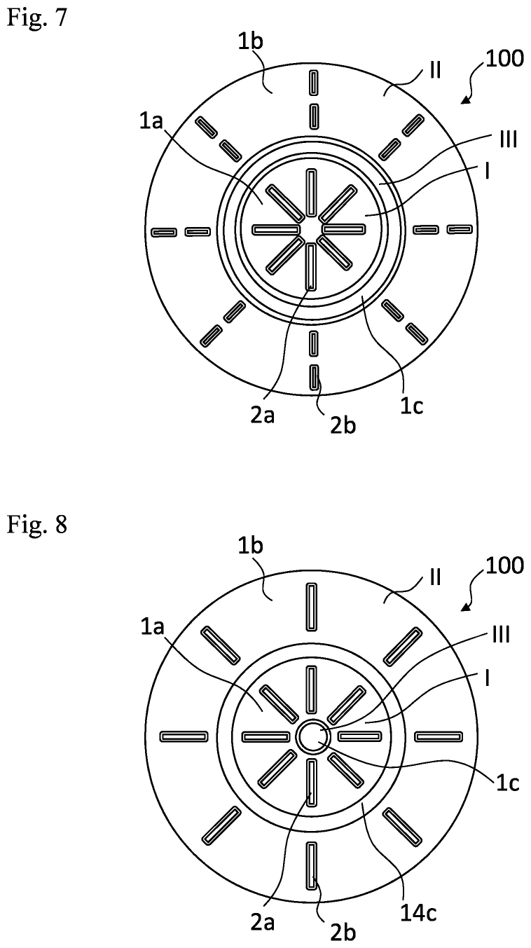

FIGS. 6 and 7 show a further exemplary embodiment of the semiconductor device in a cross-sectional view and a top view,

FIGS. 8 to 11 show further exemplary embodiments of the semiconductor device in different views and

FIG. 12 shows a flowchart of an exemplary embodiment of the method for operating a semiconductor device.

FIG. 1 shows a first exemplary embodiment of the semiconductor device 100 in a cross-sectional view. The semiconductor device 100 comprises a semiconductor body 1, which may be based on silicon. The semiconductor body 1 comprises a first side 10 and a second side 20 opposite to the first side 10. Furthermore, the semiconductor device 100 comprises a first thyristor structure I and a second thyristor structure II, which are arranged laterally beside each other but are separated from each other in lateral direction.

The first thyristor structure I comprises a gate electrode 1a and a first main electrode 2a both on the first side 10. Moreover, the first thyristor structure I comprises a second main electrode 3a on the second side 20. In the direction from the first side 10 to the second side 20, the portion of the semiconductor body 1 assigned or belonging to the first thyristor structure I comprises a first emitter region 12a, a first base region 11a, a second base region 14a and a second emitter region 13a. The first emitter region 12a and the second base region 14a are of the same first conductivity type, e.g. n-conducting. The first base region 11a and the second emitter region 13a are of the same second conductivity type, e.g. p-conducting. The first emitter region 12a may have a greater doping concentration than the second base region 14a.

The gate electrode 1a adjoins the first base region 11a in an area laterally beside the first emitter region 12a. The first main electrode 2a adjoins the first emitter region 12a. The second main electrode 3a adjoins the second emitter region 13a. The first main electrode 2a may be a cathode, the second main electrode 3a may be an anode.

The second thyristor structure II comprises the same elements as the first thyristor structure I, namely a gate electrode 1b, a first main electrode 2b, a second main electrode 3b, a first emitter region 12b, a first base region 11b, a second base region 14b and a second emitter region 13b. The order of the different regions is the same as in the first thyristor structure I. Also in the second thyristor structure II, the gate electrode 1b adjoins the first base region 11b in an area laterally beside the first emitter region 12b. The first main electrode 2b adjoins the first emitter region 12b. The second main electrode 3b adjoins the second emitter region 13b. Moreover, also in the second thyristor structure II, the first emitter region 12b and the second base region 14b are of the same conductivity type, e.g. n-conducting, whereas the first base region 11b and the second emitter region 13b are of a second conductivity type, e.g. p-conducting.

A difference between the first thyristor structure I and the second thyristor structure II is the doping concentration in the respective first base regions 11a, 11b. Although both first base regions 11a, 11b are of the same conductivity type, e.g. p-conducting, the doping concentration in the first base region 11a of the first thyristor structure I is greater than the doping concentration of the first base region 11b of the second thyristor structure II. For example, the doping concentration in the first base region 11a of the first thyristor structure I is at least 10-times or at least 100-times greater than in the first base region 11b of the second thyristor structure II.

The first base regions 11a, 11b of the two thyristor structures I, II are separated from each other in lateral direction by an n-doped separation region 14c having the same doping concentration as the second base regions 14a, 14b.

As can be further seen in FIG. 1, the second base regions 14a, 14b of the two thyristor structures I, II are realized by a second base layer 14 extending contiguously over the first I and the second II thyristor structure. Likewise, the second emitter regions 13a, 13b of the first I and second II thyristor structures are realized by a second emitter layer 13 extending contiguously over the first I and the second II thyristor structure. Also the second main electrodes 3a, 3b of the first I and the second II thyristor structure are realized by a common second electrode layer 3, which extends contiguously over the first I and the second II thyristor structure.

The gate electrodes 1a, 1b of the two thyristor structures I, II are individually and independently electrically contactable. Hence, a first gate current can first be impressed through the gate electrode 1a of the first thyristor structure I in order to turn on the first thyristor structure I. Due to the higher doping concentration in the first base layer 11a, this turn-on happens in a controlled way with a controlled increase in the anode current or a controlled decay in the anode-cathode voltage, respectively. Afterwards, a second gate current can be impressed through the gate electrode 1b of the second thyristor structure II in order to turn on the second thyristor structure II. Due to the controlled turn-on in the first thyristor structure I, a diode connected in series to the semiconductor device 100 can be protected without using a snubber.

FIG. 2 shows a second exemplary embodiment of a semiconductor device 100 in a cross-sectional view. In contrast to the first exemplary embodiment of FIG. 1, the second base layer 14 now comprises a drift layer 15 and a buffer layer 16, wherein the buffer layer 16 is arranged between the second emitter layer 13 and the drift layer 15. The buffer layer 16 has, e.g., a higher doping concentration than the drift layer 15. The drift layer 15 and the buffer layer 16 are still of the same conductivity type, e.g. the n-conducting.

With the second base layer 14 comprising the buffer layer 16 and the drift layer 15, each of the thyristor structures I, II comprises a drift region 15a, 15b and a buffer region 16a, 16b.

As can further be seen in FIG. 2, the first thyristor structure I comprises a third base region 17a between the first base region 11a and the second base region 14a. The third base region 17a is of the same conductivity type as the first base region 11a, but has a lower doping concentration. For example, the doping concentration in the third base region 17a is the same as in the first base region 11b of the second thyristor structure II.

FIG. 3 shows the exemplary embodiments of FIGS. 1 and 2 in a top view on the first side 10 of the semiconductor body 1. The dashed line in FIG. 3 indicates the cross-sectional plane for the views of FIG. 1 or 2, respectively.

As can be seen in FIG. 3, the second thyristor structure II laterally surrounds the first thyristor structure I. The first thyristor structure I is arranged in a center of the semiconductor device 100. The gate electrodes 1a, 1b of the thyristor structures I, II are each formed contiguously with a plurality of interruptions or holes. Inside the interruptions or holes, the first main electrodes 2a, 2b are located.

It is visible from FIG. 3 that the area of the first thyristor structure I is smaller than the area of the second thyristor structure II. For example, the area of the second thyristor structure is at least 60% of the total area of the semiconductor device 100.

FIG. 4 shows a further exemplary embodiment of the semiconductor device 100 in cross-sectional view. Here, an anti-parallel diode structure III is arranged laterally between the first I and the second II thyristor structure. The anti-parallel diode structure III comprises a first main electrode 1c on the first side 10 and a second main electrode 3c on the second side 20. Moreover, the anti-parallel diode structure III comprises a first diode region 18c and a second diode region 13c, 15c, 16c. The first diode region 18c may be of the same conductivity type as the first base regions 11a, 11b. For example, the first diode region 18c has the same doping concentration as the first base region 11b of the second thyristor structure II. The second diode region 13c, 15c, 16c is of the opposite conductivity type as the first diode region 18c. For example, the second diode region 13c, 15c, 16c comprises a drift region 15c, a buffer region 16c and a contact region 13c. The contact region 13c may comprise the highest doping concentration. The doping concentrations of the drift region 15c may be the same as that of the drift regions 15a, 15b of the first I and second II thyristor structure and the doping concentration of the buffer region 16c may be the same as the doping concentration of the buffer regions 16a, 16b of the first I and the second II thyristor structures.

With the anti-parallel diode structure III formed with the same semiconductor body 1 as the first I and the second II thyristor structures, the semiconductor device 100 of FIG. 4 constitutes a reverse conducting (RC) semiconductor device 100.

FIG. 5 shows the semiconductor device of FIG. 4 in top view onto the first side 10 of the semiconductor body 1.

FIG. 6 shows a further exemplary embodiment of the semiconductor device 100 in cross-sectional view. The difference to the exemplary embodiment of FIGS. 4 and 5 is that the second thyristor structure II is now realized as a commutated-gate transistor structure with a plurality of thyristor cells. Each thyristor cell is assigned its own first emitter region 12b and its own first main electrode 2b. The semiconductor device of FIG. 100 is, e.g., an RC-IGCT.

FIG. 7 shows the semiconductor device 100 of FIG. 6 in top view onto the first side 10 of the semiconductor body 1.

FIG. 8 shows a further exemplary embodiment of the semiconductor device 100 in top view onto the first side 10. In contrast to the previous exemplary embodiment, the anti-parallel diode structure III is now arranged in a center of the semiconductor device 100 and is laterally surrounded by the first I and the second II thyristor structure. The two thyristor structures I, II or their first base regions 11a, 11b, respectively, are separated from each other by the separation region 14c.

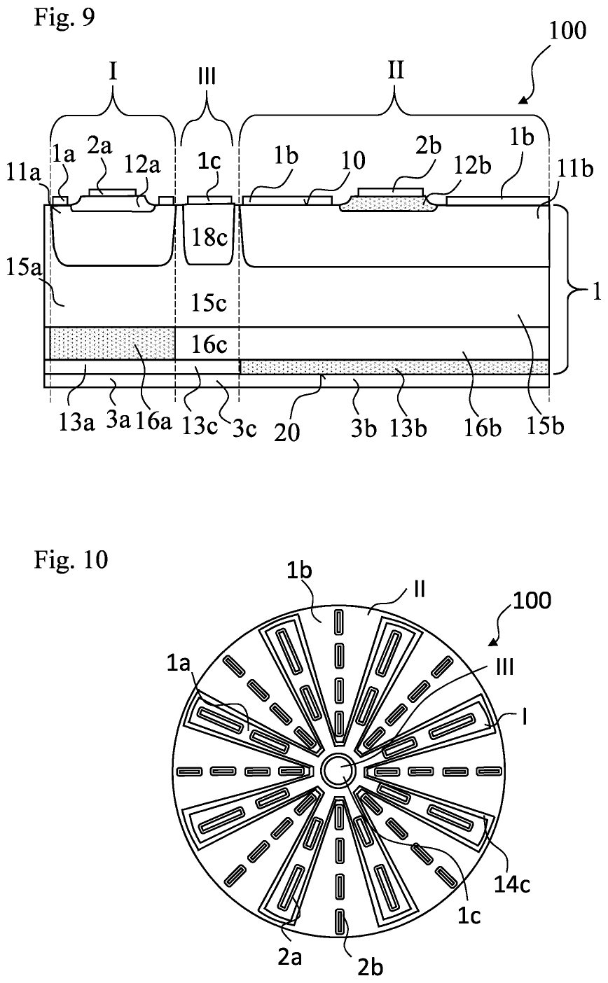

FIG. 9 shows a further exemplary embodiment of the semiconductor device 100 in cross-sectional view. Here, the first base regions 11a, 11b may have the same doping concentration. The first emitter region 12b of the second thyristor structure II has a higher doping concentration than the first emitter region 12a of the first thyristor structure I. The second emitter region 13b of the second thyristor structure II has a higher doping concentration than the second emitter region 13a of the first thyristor structure I. The buffer region 16a of the first thyristor structure I has a higher doping concentration than the buffer region 16b of the second thyristor structure II. By each of these differences in the doping concentration, a similar effect as described with respect to FIG. 1 can be achieved, namely that the first thyristor structure I can be turned-on in a controlled way and the associated controlled decay of the anode-cathode voltage can then be smoothly handed over to the second thyristor structure II.

Notably, it is sufficient to have a difference of the doping concentration in one region of the first I and the second II thyristor structure, e.g. only in the first base regions 11a, 11b or only in the second base regions 14a, 14b or only in the first emitter regions 12a, 12 or only in the second emitter regions 13a, 13b, for achieving the above mentioned effect. However, any combination of differently doped regions, like in the exemplary embodiment of FIG. 9 with three regions (second base regions, first emitter regions and second emitter regions) being doped differently, is possible, e.g. all four regions being doped differently is possible.

FIG. 10 shows a further exemplary embodiment of the semiconductor device 100 in top view onto the first side 10. Here, the first thyristor structure I and the second thyristor structure II are arranged in an alternating manner along a lateral direction. The first thyristor structure I engages with the second thyristor structure II in a comb-like manner so that a circle line around a center of the semiconductor device 100 alternately crosses sections of the first I and the second II thyristor structure. The arrangement of FIG. 10 is beneficial in terms of thermal management.

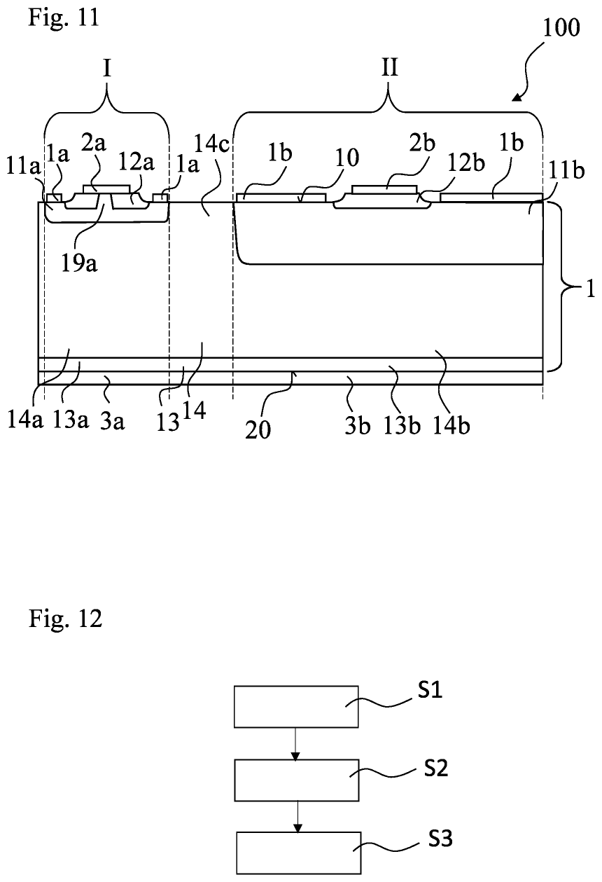

FIG. 11 shows a further exemplary embodiment of the semiconductor device 100 in cross-sectional view. The difference to the previous exemplary embodiments is a short 19a, also referred to as emitter short, through the first emitter region 12a of the first thyristor structure I. The short 19a electrically connects the first main electrode 2a with the first base region 11a. The short 19a is a region of the semiconductor body 1 and has, e.g., the same doping concentration and the same conductivity type as the first base region 11a, hence is of the opposite conductivity type than the first emitter region 12a. With this short 19a, the first thyristor structure I will not latch when turned on.

In FIG. 11, the doping concentrations of all corresponding regions of the first I and second II thyristor structure are the same. This is only an example and, instead, the doping concentrations may also be chosen differently, e.g. as in FIG. 1 and/or FIG. 9.

FIG. 12 shows a flowchart of an exemplary embodiment of the method for operating a semiconductor device of any of the previous figures. In a step S1, a first gate current is impressed through the gate electrode 1a of the first thyristor structure I and no gate current is impressed through the gate electrode 1b of the second thyristor structure II.

Then, in a step S2, a second gate current is impressed through the gate electrode 1b of the second thyristor structure II. This second step S2 may be performed only after a voltage decay between the anode and the cathode has appeared. The semiconductor device 100 is now turned on.

Then, later on, in a step S3, a turn-off gate current is impressed through the gate electrodes 1b of the second thyristor structures II. The semiconductor device 100 is now turned off.

The embodiments shown in the FIGS. 1 to 12 as stated represent exemplary embodiments of the semiconductor device and the method for operating a semiconductor device. Therefore, they do not constitute a complete list of all embodiments according to the semiconductor device and the method for operating the semiconductor device. Actual semiconductor devices and methods may vary from the embodiments shown in terms of arrangements, devices and elements for example.

Reference Signs

| | |
|---|---|
| 1 | semiconductor body |
| 1a, 1b | gate electrode |
| 1c | first main electrode |
| 2a, 2b | first main electrode |
| 3a, 3b, 3c | second main electrode |
| 10 | first side |
| 11a, 11b | first base region |
| 12a, 12b | first emitter region |
| 13a, 13b | second emitter region |
| 14a, 14b | second base region |
| 14c | separation region |
| 14 | second base layer |
| 15a, 15b, 15c | drift region |
| 15 | drift layer |
| 16a, 16b, 16c | buffer region |
| 16 | buffer layer |
| 17a | third base region |
| 18c | first diode region |
| 19a | short |
| 20 | second side |
| 100 | semiconductor device |
| I | first thyristor structure |
| II | second thyristor structure |
| III | diode structure |
| S1, S2, S3 | method steps |

1. A semiconductor device comprising
a semiconductor body comprising a first side and a second side opposite to the first side,
a first thyristor structure; and
a second thyristor structure laterally beside the first thyristor structure, wherein
each of the first thyristor structure and the second thyristor structure comprises a first base region at the first side and a gate electrode on the first side adjoining and being in electrical contact with the first base region,
the first base region is of a same conductivity type and are each a region of the semiconductor body, wherein at least one region of the semiconductor body assigned to the first thyristor structure has a different doping concentration than a corresponding region of the semiconductor body assigned to the second thyristor structure,
the gate electrode is are individually and independently electrically contactable, and
doping concentrations in the first thyristor structure are adjusted such that, when turned on by a gate current impressed through the gate electrode, the first thyristor structure does not latch.

2. (canceled)

3. The semiconductor device according to claim 1, wherein
the first base region of the first thyristor structure has a greater doping concentration than the first base region of the second thyristor structure.

4. The semiconductor device according to claim 1, wherein the semiconductor device comprises a diode structure arranged laterally beside the first and the second thyristor structure.

5. The semiconductor device according to claim 1, wherein, an area of the first thyristor structure is smaller than a area of the second thyristor structure.

6. The semiconductor device according to claim 1, wherein the second thyristor structure is a gate-commutated thyristor structure with a plurality of thyristor cells.

7. The semiconductor device according to claim 1, wherein
the first base region is separated from each other by at least one separation region of the semiconductor body being of a different conductivity type than the first base region,
the first base region of the first thyristor structure is formed contiguously, and
the first base region of the second thyristor structure is formed contiguously.

8. The semiconductor device according to claim 1, wherein
each of the first and the second thyristor structure comprises a first main electrode on the first side, a second main electrode on the second side, a first emitter region at the first side adjoining and being in electrical contact with the first main electrode, a second emitter region at the second side adjoining and being in electrical contact with the second main electrode and a second base region,
the first emitter region, the second emitter region and the second base region is each a region of the semiconductor body,
the first emitter region and the second base region are each of a first conductivity type,
the first base region and the second emitter region is each of a second conductivity type,
in vertical direction, the second base region is each arranged between the second emitter region and the first base region, and
in vertical direction, the first base region is each arranged between the first emitter region and the second base region.

9. The semiconductor device according to claim 8, wherein
the first emitter region of the first thyristor structure has a lower doping concentration than the first emitter region of the second thyristor structure, and/or
the second emitter region of the first thyristor structure has a lower doping concentration than the second emitter region of the second thyristor structure, and/or
the second base region of the first thyristor structure has greater doping concentration than the second base region of the second thyristor structure.

10. The semiconductor device according to claim 8, wherein the first emitter region of the first thyristor structure is passed through by one or more shorts which are of an opposite conductivity type than the first emitter region and which electrically connect the first base region with the first main electrode of the first thyristor structure.

11. The semiconductor device according to claim 8, wherein
the second base region each comprise a drift region and a buffer region that has a greater doping concentration than the drift region, and
wherein the buffer region separates the drift region from the second emitter region.

12. The semiconductor device according to claim 1, wherein in a lateral direction, the first thyristor structure and the second thyristor structure are arranged in an alternating manner.

13. Method for operating a semiconductor device according to claim 1 comprising:
impressing a first gate current through the gate electrode of the first thyristor structure while no current is impressed through the gate electrode of the second thyristor structure; and
impressing a second gate current through the gate electrode of the second thyristor structure.

14. Method according to claim 13, wherein the second gate current is impressed after a decay of an anode-cathode voltage in the semiconductor device.

15. Semiconductor module comprising:
the semiconductor device according to claim 8; and
a housing for the semiconductor device, the semiconductor device comprising:
two main electrode structures for electrically contacting the first main electrode and the second main electrode of the thyristor structures of the semiconductor device;
a first auxiliary electrode structure for electrically contacting the gate electrode of the first thyristor structure; and
a second, separate auxiliary electrode structure for electrically contacting the gate electrode of the second thyristor structure.
